(19) United States
(12) Patent Application Publication
(10) Pub. No.: US 2006/0113683 A1
(43) Pub. Date: Jun. 1, 2006

(54) Doped alloys for electrical interconnects, methods of production and uses thereof

(76) Inventors: Nancy Dean, Ann Arbor, MI (US); James Flint, Mead, WA (US); John Lalena, Fairchild AFB, WA (US); Martin Weiser, Liberty Lake, WA (US)

Correspondence Address: Sandra Poteat Thompson;Nemer A Professional Law Corporation, 18400 Von Karman, Suite 800, Irvine, CA, 92612, US

(21) Appl. No.: 11/147,958

(22) Filed: Jun. 8, 2005

(30) Foreign Application Priority Data
Sep. 7, 2004 (WO) PCT/US04/28837

(51) Int. Cl. H01L 23/48; C22C 13/00; C22C 5/08

(52) U.S. Cl. 257/783; 257/782; 257/779; 420/560; 420/502

(57) ABSTRACT

Lead free solder compositions are described herein that include at least one solder material; at least one dopant material, wherein the dopant is present in the material in an amount of less than about 1000 ppm, and wherein the solder composition is substantially lead free. Several doped solder compositions described herein comprise at least one solder material, at least one phosphorus-based dopant and at least one copper-based dopant. Methods of forming doped solder materials include: a) providing at least one solder material; b) providing at least one phosphorus-based dopant; c) providing at least one copper-based dopant, and d) blending the at least one solder material, the at least one phosphorus-based dopant and the at least one copper-based dopant to form a doped solder material. Layered materials are also described herein that comprise: a) a surface or substrate; b) an electrical interconnect; c) a solder composition comprising at least one solder material; at least one dopant material, wherein the dopant is present in the material in an amount of less than about 1000 ppm, and wherein the solder composition is substantially lead free. Layered materials are also described herein that comprise: a) a surface or substrate; b) an electrical interconnect; c) a solder composition comprising at least one phosphorus-based dopant and at least one copper-based dopant, such as those described herein, and d) a semiconductor die or package. Electronic and semiconductor components that comprise solder compositions and/or layered materials described herein are also contemplated.

This application is a utility application based on PCT Application Ser. No.: PCT/US04/28837 filed on Sep. 7, 2004, which is based on U.S. Provisional Application Ser. No. 60/501,384, both of which are commonly owned and incorporated herein in their entirety by reference.

### FIELD OF THE SUBJECT MATTER

The field of the invention is doped and lead-free thermal interconnect systems, thermal interface systems and interface materials in electronic components, semiconductor components and other related layered materials applications.

### BACKGROUND OF THE SUBJECT MATTER

Electronic components are used in ever increasing numbers of consumer and commercial electronic products. Examples of some of these consumer and commercial products are televisions, personal computers, Internet servers, cell phones, pagers, palm-type organizers, portable radios, car stereos, or remote controls. As the demand for these consumer and commercial electronics increases, there is also a demand for those same products to become smaller, more functional, and more portable for consumers and businesses.

As a result of the size decrease in these products, the components that comprise the products must also become smaller. Examples of some of those components that need to be reduced in size or scaled down are printed circuit or wiring boards, resistors, wiring, keyboards, touch pads, and chip packaging.

Components, therefore, are being broken down and investigated to determine if there are better building and intermediate materials, machinery and methods that will allow them to be scaled down to accommodate the demands for smaller electronic components. Part of the process of determining if there are better building materials, machinery and methods is to investigate how the manufacturing equipment and methods of building and assembling the components operates.

Numerous known die attach methods utilize a high-lead solder, solder compositions or solder material to attach the semiconductor die within an integrated circuit to a leadframe for mechanical connection and to provide thermal and electrical conductivity between the die and leadframe. Although most high-lead solders are relatively inexpensive and exhibit various desirable physico-chemical properties, the use of lead in die attach and other solders has come under increased scrutiny from an environmental and occupational health perspective. Consequently, various approaches have been undertaken to replace lead-containing solders with lead-free die attach compositions.

For example, in one approach, polymeric adhesives (e.g., epoxy resins or cyanate ester resins) are utilized to attach a die to a substrate as described in U.S. Pat. Nos. 5,150,195; 5,195,299; 5,250,600; 5,399,907 and 5,386,000. Polymeric adhesives typically cure within a relatively short time at temperatures generally below 200° C., and may even retain structural flexibility after curing to allow die attach of integrated circuits onto flexible substrates as shown in U.S. Pat. No. 5,612,403. However, many polymeric adhesives tend to produce resin bleed, potentially leading to undesirable reduction of electrical contact of the die with the substrate, or even partial or total detachment of the die.

To circumvent at least some of the problems with resin bleed, silicone-containing die attach adhesives may be utilized as described in U.S. Pat. No. 5,982,041 to Mitani et al. While such adhesives tend to improve the bonding of the wire, as well as that between the resin sealant and the semiconductor chip, substrate, package, and/or lead frame, the curing process for at least some of such adhesives requires a source of high-energy radiation, which may add significant cost to the die attach process.

Alternatively, a glass paste comprising a high-lead borosilicate glass may be utilized as described in U.S. Pat. No. 4,459,166 to Dietz et al., thereby generally avoiding a high-energy curing step. However, many glass pastes comprising a high-lead borosilicate glass require temperatures of 425° C. and higher to permanently bond the die to the substrate. Moreover, glass pastes frequently tend to crystallize during heating and cooling, thereby reducing the adhesive qualities of the bonding layer.

In yet another approach, various high melting solders are utilized to attach a die to a substrate or leadframe. Soldering a die to a substrate has various advantages, including relatively simple processing, solvent-free application, and in some instances relatively low cost. There are various high melting solders known in the art. However, all or almost all of them have one or more disadvantages. For example, most gold eutectic alloys (e.g., Au-20% Sn, Au-3% Si, Au-12% Ge, and Au-25% Sb) are relatively costly and frequently suffer from less-than-ideal mechanical properties. Alternatively, Alloy J (Ag-10% Sb-65% Sn, see e.g., U.S. Pat. No. 4,170,472 to Olsen et al.) may be used in various high melting solder applications. However, Alloy J has a solidus of 228° C. and also suffers from relatively poor mechanical performance.

For those components that require electronic interconnects, the spheres, balls, powder, preforms or some other solder-based component that can provide an electrical interconnect between two components are utilized. In the case of BGA spheres, the spheres form the electrical interconnect between a package and a printed circuit board and/or the electrical interconnection between a semiconductor die and package or board. The locations where the spheres contact the board, package or die are called bond pads. The interaction of the bond pad metallurgy with the sphere during solder reflow can determine the quality of the joint, and little interaction or reaction will lead to a joint that fails easily at the bond pad. Too much reaction or interaction of the bond pad metallurgy can lead to the same problem through excessive formation of brittle intermetallics or undesirable products resulting from the formation of intermetallics.

There are several approaches to correct and/or reduce some of the solder problems presented herein. For example, Japanese patent, JP07195189A, uses bismuth, copper and antimony simultaneously as dopants in a BGA sphere to improve joint integrity. Phosphorous may or may not be added; however, results in this patent show that phosphorus additions performed poorly. Phosphorus was added in high weight percentages, as compared to other components. Levels of copper ranged from 100 ppm to 1000 ppm.

In “Effect of Cu Concentration on the reactions between Sn—Ag—Cu Solders and Ni”, Journal of Electronic Materials, Vol. 31, No 6, p 584, 2002 by C. E. Ho, et. al, and Republic of China Patent 1490961 (Mar. 23, 2001); C. R. Kao and C. E Ho, the effect of copper additions on improving Sn—Pb eutectic performance on ENIG bond pads is investigated. Compositions comprising less than 2000 ppm Cu were not investigated.

Jeon, et. al, “Studies of Electroless Nickel Under Bump Metallurgy—Solder Interfacial Reactions and Their Effects on Flip Chip Joint Reliability”, Journal of Electronic Materials, pg 520-528, Vol 31, No 5, 2002, and Jeon et. al, “Comparison of Interfacial Reactions and Reliabilities of Sn3.5Ag and Sn4.0Ag0.5Cu and Sn0.7Cu Solder Bumps on Electroless Ni—P UBMs” Proceeding of Electronic Components and Technology Conference, IEEE, pg 1203, 2003 discuss that intermetallic growth is faster on pure nickel bond pads than electroless nickel bonds pads. The benefits of copper in concentrations of 0.5% (5000 ppm) or higher are also investigated and discussed in both articles.

Zhang, et. al, “Effects of Substrate Metallization on Solder/UnderBump Metallization Interfacial Reactions in Flip-Chip Packages, during Multiple Reflow Cycles”, Journal of Electronic Materials, Vol 32, No 3, pg 123-130, 2003 shows there is no effect from phosphorus on slowing intermetallic consumption (which contradicts the Jeon article). Shing Yeh, “Copper Doped Eutectic Tin-Lead Bump for Power Flip Chip Applications”, Proceeding of Electronic Components and Technology Conference, IEEE, pg 338, 2003 notes that a 1% copper addition reduced nickel layer consumption.

The Niedrich patents and application (EP0400363 A1 EP0400363B1 and U.S. Pat. No. 5,011,658) show copper used as a dopant in Sn—Pb—In solders to minimize the consumption of copper bond pads or connectors (i.e., no nickel barrier layer is used). The copper in the solder was found to decrease the copper connector dissolution. Niedrich uses the copper to inhibit nickel barrier layer interaction through forming copper intermetallics or (Cu, Ni)Sn intermetallics. The Niedrich patents are very similar in their use of copper as U.S. Pat. No. 2,671,844, which adds copper to solder in amounts greater than 0.5 wt % to minimize dissolution of copper soldering iron tips during fine soldering operations.

The U.S. Issued Pat. No. 4,938,924 by Ozaki noted that the addition of 2000-4000 ppm of copper improves wetting and long term joint reliability of in Sn-36Pb-2Ag alloys. Japanese Patent JP60166191A “Solder Alloy Having Excellent Resistance to Fatigue Characteristic” discloses a Sn Bi Pb alloy with 300-5000 ppm copper added to improve fatigue resistance.

U.S. Issued Pat. No. 6,307,160 teaches the use of at least 2% indium to improve the bond strength of the eutectic Sn—Pb alloy on Electroless Nickel/Immersion Gold (ENIG) bond pads.

U.S. Issued Pat. No. 4,695,428 “Solder Composition” discloses a Pb-free solder composition used for plumbing joints. The copper concentration used is in excess of 1000 ppm and several other elements are also added as alloying additions to improve the liquidus, solidus, flow properties and surface finish of the solder.

U.S. Issued Pat. No. 2,303,193A, teaches the use of 0.1-1.5% Cu (1000-15,000 ppm Cu) in addition to Cd and Sb to increase the creep resistance of the solder. The reference specifically states “copper in less than the amount indicated is not sufficient materially to improve the durability over ordinary lead-tin alloys.”

Thus, there is a continuing need to: a) develop lead-free doped solder materials that function in a similar manner as lead-based or lead-containing solder materials; b) develop solder materials and solder dopants that have no deleterious effects on bulk solder properties, yet slows the consumption of the nickel-barrier layer and hence, in some cases, growth of a phosphorus rich layer, so that bond integrity is maintained during reflow and post reflow thermal aging; c) design and produce electrical interconnects that meet customer specifications while minimizing the production costs and maximizing the quality of the product incorporating the electrical interconnects; and d) develop reliable methods of producing electrical interconnects and components comprising those interconnects.

### SUMMARY

Lead free solder compositions are described herein that include at least one solder material; at least one dopant material, wherein the dopant is present in the material in an amount of less than about 1000 ppm, and wherein the solder composition is substantially lead-free.

Several doped solder compositions described herein comprise at least one solder material, at least one phosphorus-based dopant and at least one copper-based dopant. Methods of forming doped solder materials include: a) providing at least one solder material; b) providing at least one phosphorus-based dopant; c) providing at least one copper-based dopant, and d) blending the at least one solder material, the at least one phosphorus-based dopant and the at least one copper-based dopant to form a doped solder material.

Layered materials are also described herein that comprise: a) a surface or substrate; b) an electrical interconnect; c) a solder composition comprising at least one solder material; at least one dopant material, wherein the dopant is present in the material in an amount of less than about 1000 ppm, and wherein the solder composition is substantially lead free.

Layered materials are also described herein that comprise: a) a surface or substrate; b) an electrical interconnect; c) a solder composition comprising at least one phosphorus-based dopant and at least one copper-based dopant, such as those described herein, and d) a semiconductor die or package. Electronic and semiconductor components that comprise solder materials and/or layered materials described herein are also contemplated.

### BRIEF DESCRIPTION OF THE DRAWINGS

FIG. 1 is a Ag—Bi phase diagram.

FIG. 2 is an electron micrograph of an exemplary Ag—Bi alloy.

FIG. 3 is a Ge—Ni phase diagram.

FIG. 4 is a graph depicting thermal conductivity of Ag—Bi with varying Ag content.

FIGS. 5A and 5B are graphs depicting wetting forces of contemplated alloys on various substrates.

FIG. 6 is a table showing calculated contact angles of various alloys.

FIG. 7 is a photograph of exemplary wetting behavior of contemplated alloys on Ni-plated leadframes with various concentrations of germanium.

FIG. 8 is a schematic vertical cross section of a contemplated electronic device.

FIGS. 9A and 9B are photographs/SAM-microscopy photographs of dies attached to leadframes using exemplary alloys.

FIG. 10A is a Ni—Bi phase diagram.

FIG. 10B is an electron micrograph of an exemplary alloy with specific regard to Ni and Bi.

FIGS. 11A and B are electron micrographs of substrates showing completed Ag scavenging.

FIG. 12 is a table summarizing various physical properties of various alloys.

### DESCRIPTION OF THE SUBJECT MATTER

Unlike the previously described references, doped solder materials and solder dopants have been developed and are described herein that are lead free and that function in a similar manner as lead-based or lead-containing solder materials; that have no deleterious effects on bulk solder properties, yet slow the consumption of the nickel-barrier layer and hence, in some cases, growth of a phosphorus rich layer, so that bond integrity is maintained during reflow and post reflow thermal aging. These solder dopants meet both goals of a) designing and producing electrical interconnects that meet customer specifications while minimizing the production costs and maximizing the quality of the product incorporating the electrical interconnects; and b) developing reliable methods of producing electrical interconnects and components comprising those interconnects.

Lead free solder compositions are described herein that include at least one solder material; at least one dopant material, wherein the dopant is present in the material in an amount of less than about 1000 ppm, and wherein the solder composition is substantially lead free.

The lead-free solder material may comprise any suitable solder material, alloy or metal, such as indium, silver, copper, aluminum, tin, bismuth, gallium and alloys thereof, silver coated copper, silver coated aluminum or a combination thereof. Preferred solder materials may comprise tin-based alloys, including indium tin (InSn) compounds and alloys, indium silver (InAg) compounds and alloys, silver-based compounds and alloys, indium-based compounds, tin silver copper compounds (which already comprise copper) and alloys (SnAgCu), tin bismuth compounds and alloys (SnBi), aluminum-based compounds and alloys and combinations thereof. It should be understood that the solder compositions and materials contemplated herein are substantially lead-free, wherein “substantially” means that the lead present is a contaminant and not considered a dopant or an alloying material.

As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Contemplated metals include such as indium, silver, copper, aluminum, tin, bismuth, gallium and alloys thereof, silver coated copper, and silver coated aluminum. The term “metal” also includes alloys, metal/metal composites, metal ceramic composites, metal polymer composites, as well as other metal composites. As used herein, the term “compound” means a substance with constant composition that can be broken down into elements by chemical processes.

It has been discovered that, among other desirable properties, contemplated compositions may advantageously be utilized as near drop-in replacements for high-lead containing solders in various die attach applications. In some cases, contemplated compositions are lead-free alloys having a solidus of no lower than about 240° C. and a liquidus no higher than about 500° C., and in other cases no higher than about 400° C. Various aspects of the contemplated methods and compositions are disclosed in PCT application PCT/US01/17491 incorporated herein in its entirety.

As discussed herein, contemplated lead-free and doped solder compositions or materials comprise dopants in an amount of up to about 1000 ppm. These dopants may be any suitable metal or non-metal dopant, as long as the dopant is not lead or lead-based. The dopant may also be present as a combination of dopants. In these embodiments, where combinations of dopants are added, the dopant concentration may add up to a total of about 1000 ppm or the individual dopants may be present in amounts of up to 1000 ppm. It should again be understood however that dopants do not perform as alloying elements in the solder material or composition. Contemplated dopants include Al, Au, As, Ba, Ca, Ce, Cs, Hf, Li, Mg, Nd, P, Sc, Sr, Ti, Y, Ge, Zr, Cu, Ni, Zn, Sn, In, Sb, Pt or combinations thereof.

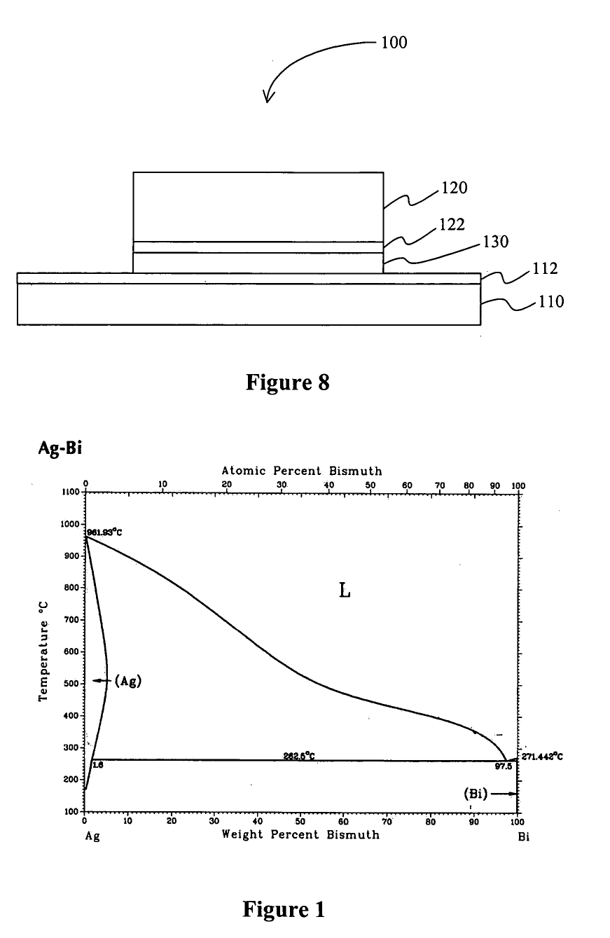

A group of contemplated compositions comprise binary alloys that may be used as solder and that comprise silver in an amount of about 2 wt % to about 18 wt % and bismuth in an amount of about 98 wt % to about 82 wt %. FIG. 1 shows an Ag—Bi phase diagram. Compositions contemplated herein can be prepared by a) providing a charge of appropriately weighed quantities (supra) of the pure metals; b) heating the metals under vacuum or an inert atmosphere (e.g., nitrogen or helium) to between about 960° C.-1000° C. in a refractory or heat resistant vessel (e.g., a graphite crucible) until a liquid solution forms; and c) stirring the metals at that temperature for an amount of time sufficient to ensure complete mixing and melting of both metals. Nickel, zinc, germanium, copper, calcium or combinations thereof are added to the charge or molten material at dopant quantities of up to about 1000 ppm, and more preferably of up to about 500 ppm.

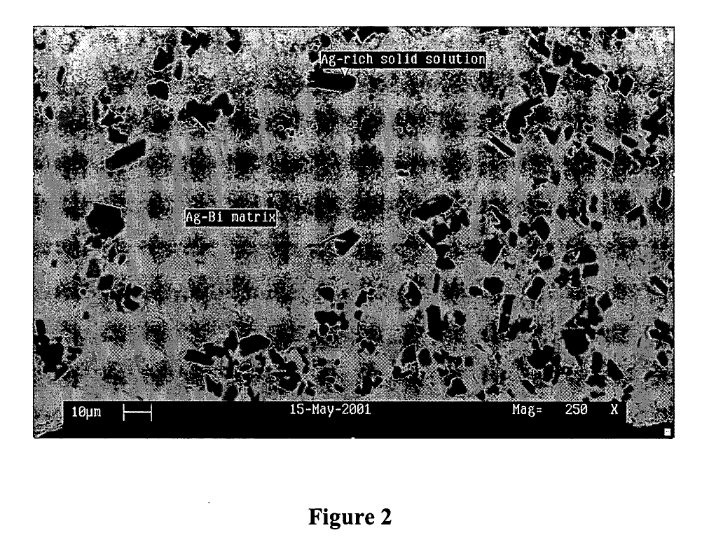

The molten mixture, or melt, is then quickly poured into a mold, allowed to solidify by cooling to ambient temperature, and fabricated into wire by conventional extrusion techniques, which includes heating the billet to approximately 190° C., or into ribbon by a process in which a rectangular slab is first annealed at temperatures between about 225-250° C. and then hot-rolled at the same temperature. Alternatively, a ribbon may be extruded that can subsequently be rolled to thinner dimensions. The melting step may also be carried out under air so long as the slag that forms is removed before pouring the mixture into the mold. FIG. 2 shows an electron micrograph, in which the Ag—Bi alloy appears to form a hypoeutectic alloy wherein the primary constituent (silver) is surrounded by fine eutectic structure. As can be seen from the electron micrograph, there is only negligible mutual solubility in the material, thus resulting in a more ductile material than bismuth metal.

In other embodiments, especially where higher liquidus temperatures are desired, contemplated compositions may include different percentages of alloying materials, such as Ag in the alloy in an amount of about 7 wt % to about 18 wt % and Bi in an amount of about 93 wt % to about 82 wt %. On the other hand, where relatively lower liquidus temperatures are desired, contemplated compositions may include similar materials in different percentages, such as Ag in the alloy in an amount of about 2 wt % to about 7 wt % and Bi in an amount of about 98 wt % to about 93 wt %. Some die attach applications may utilize a composition in which Ag is present in the alloy in an amount of about 5 wt % to about 12 wt % and Bi in an amount of about 95 wt % to about 88 wt %. For these embodiments, an exemplary alloy may have the composition of Bi at about 89 wt % and Ag at about 11 wt %.

At this point it should be understood that, unless otherwise indicated, all numbers expressing quantities of ingredients, constituents, reaction conditions and so forth used in the specification and claims are to be understood as being modified in all instances by the term “about”. Accordingly, unless indicated to the contrary, the numerical parameters set forth in the specification and attached claims are approximations that may vary depending upon the desired properties sought to be obtained by the subject matter presented herein. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the subject matter presented herein are approximations, the numerical values set forth in the specific examples are reported as precisely as possible. Any numerical value, however, inherently contain certain errors necessarily resulting from the standard deviation found in their respective testing measurements.

It should be particularly appreciated that these contemplated and novel compositions may be utilized as lead-free solders that are also essentially devoid of Sn as an alloying element, which is a common and predominant component in known lead-free solder. If tin is added to the novel compositions described herein, it is added as a dopant and not for the purposes of alloying. Moreover, while it is generally contemplated that particularly suitable compositions are binary alloys, it should also be appreciated that alternative compositions may include ternary, quaternary, and higher alloys, as long as there is at least one dopant included in the composition.

Some contemplated compositions may include one or more dopants having an oxygen affinity that is higher than the oxygen affinity of at least one of the primary constituents of the alloy (without the chemical element). These chemical elements comprise Al, Ba, Ca, Ce, Cs, Hf. Li, Mg, Nd, P, Sc, Sr, Ti, Y, Ge, Zr or combinations thereof, and it is further contemplated that such chemical elements may be present in the alloy at a concentration of less than about 1000 ppm, and in some embodiments, between about 10 ppm (and less) and approximately 1000 ppm. While not wishing to be bound to a particular theory or mechanism, it is contemplated that elements having a higher oxygen affinity than the alloy reduce the formation of metal oxides that are known to increase the surface tension of a melting or molten solder. Therefore, it is contemplated that a decrease in the amount of metal oxides during soldering will generally reduce the surface tension of the molten solder, and thereby significantly increases the wetting ability of the solder.

One or more metal dopants may also be added to improve thermo-mechanical pro-perties (e.g., thermal conductivity, coefficient of thermal expansion, hardness, paste range, ductility, wettability to various metal-plated substrates, etc.) of the doped lead-free solder. Contemplated metals comprise indium, tin, antimony, zinc, nickel or combinations thereof. However, various metals other than the aforementioned metals are also suitable for use in conjunction with the teachings presented herein, so long as such metals improve at least one thermo-mechanical property. Consequently, further contemplated metals comprise copper, gold, germanium, arsenic or combinations thereof.

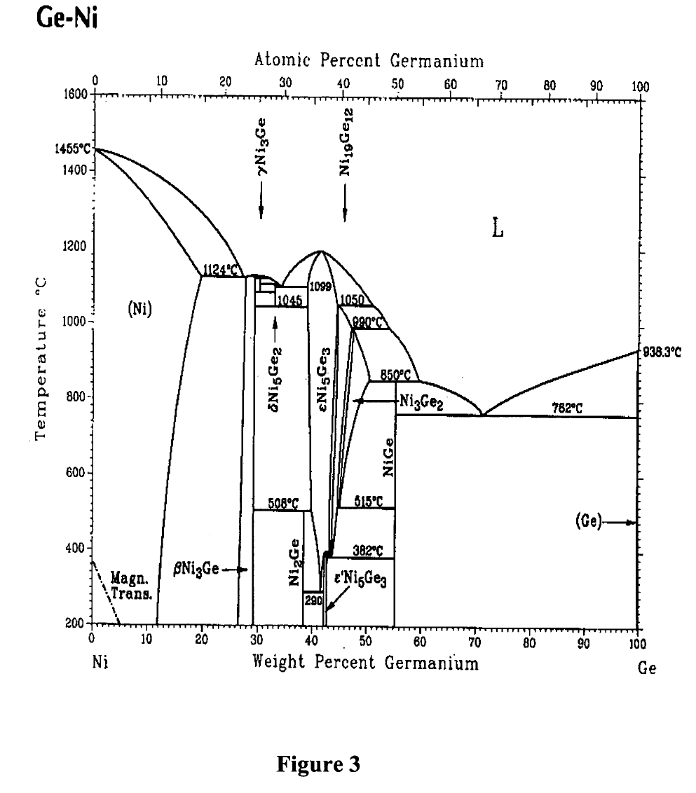

Some contemplated alloys may include Ag in an amount of about 2 wt % to about 18 wt %, Bi in an amount of about 98 wt % to about 82 wt %, and a third element in an amount of up to about 1000 ppm, and in some embodiments, within the range of about 10 ppm to about 1000 ppm, depending on the particular thermo-mechanical property. Exemplary contemplated third elements include at least one of Au, Cu, Pt, In, Sn, Ni, Zn or combinations thereof, and especially contemplated third elements are at least one of zinc, nickel, germanium and/or a combination thereof.

Where the third element comprises at least one of zinc, nickel, germanium, copper, calcium or a combination thereof, it is contemplated that the at least one of zinc, nickel, germanium, copper, calcium or a combination thereof is present in preferred alloys in an amount of less than 1000 ppm, and in some embodiments, in an amount within a range of between about 10 ppm and about 1000 ppm, more typically in a range of between about 200 ppm and about 700 ppm, and most typically at a concentration of about 500 ppm. Addition of the at least one of zinc, nickel, germanium, copper, calcium or a combination thereof was observed to improve wettability to substrates plated with various metals, particularly including copper and nickel, or a bare metal that has not been plated, such as a leadframe, where the at least one of zinc, nickel, germanium, calcium, copper or a combination thereof were added in amounts of less-than about 100 ppm and in some embodiments, between about 10 ppm to about 100 ppm. While not wishing to be bound to a particular theory, it is contemplated that the at least one of zinc, nickel, germanium, calcium, copper or a combination thereof may advantageously form intermetallic complexes with Ni, or reduce an oxide film by allowing preferential oxidation, and thereby contribute to the increase in the wetting force. A Ni—Ge phase diagram is depicted in FIG. 3, indicating the potential for various Ni-Ge intermetallic complexes and partial Ge—Ni solid solubility. Furthermore, it is contemplated that a preferential surface oxidation of germanium may occur. Based on this discussion, a contemplated composition includes an alloy comprising (or consisting of) Bi at about 89 wt %, Ag at about 11 wt %, and the at least one of zinc, nickel, germanium, copper, calcium or a combination thereof in a range between about 10 ppm and about 1000 ppm, more preferably about 500 ppm. Such contemplated alloys may further include phosphorus in an amount of up to about 1000 ppm, and more typically about 200 ppm. Furthermore, it should be appreciated that addition of Ge of up to about about 1000 ppm will not significantly lower the solidus of such compositions. While in some embodiments alloys comprise Ge in an amount of up to about 1000 ppm, it should also be recognized that Ge may also be present as dopant in concentrations of less than 10 ppm and in some cases, less than about 1 ppm.

Consequently, and depending on the concentration/amount of the third element, it should be recognized that such alloys will have a solidus of no lower than about 230° C., more preferably no lower than about 248° C., and most preferably no lower than about 258° C. and a liquidus of no higher than about 500° C. and in some cases no higher than about 400° C. Especially contemplated uses of such alloys includes die attach applications (e.g., attachment of a semiconductor die to a substrate). Consequently, it is contemplated that an electronic device will comprise a semiconductor die coupled to a surface via a material comprising the composition that includes contemplated ternary (or higher) alloys. With respect to the production of contemplated ternary alloys, the same considerations as outlined above apply. In general, it is contemplated that the third element (or elements) is/are added in appropriate amounts to the binary alloy or binary alloy components.

It should further be appreciated that addition of chemical elements or metals to improve one or more physico-chemical or thermo-mechanical properties can be done in any order so long as all components in the alloy are substantially (i.e., at least 95% of each component) molten, and it is contemplated that the order of addition is not limiting to the inventive subject matter. Similarly, it should be appreciated that while it is contemplated that silver and bismuth are combined prior to the melting step, it is also contemplated that the silver and bismuth may be melted separately, and that the molten silver and molten bismuth are subsequently combined. A further prolonged heating step to a temperature above the melting point of silver may be added to ensure substantially complete melting and mixing of the components. It should be particularly appreciated that when one or more additional elements are included, the solidus of contemplated alloys may decrease. Thus, contemplated alloys with such additional alloys may have a solidus in the range of about 260-255° C., in the range of about 255-250° C., in the range of about 250-245° C., in the range of about 245-235° C., and even lower.

Where additional elements and dopants are added, it is contemplated that the at least one of the additional elements and/or dopants may be added in any suitable form (e.g., powder, shot, or pieces) in an amount sufficient to provide the desired concentration of the at least one of the additional elements and/or dopants, and the addition of the third element/elements may be prior to, during, or after melting the components for the binary alloy, such as Bi and Ag.

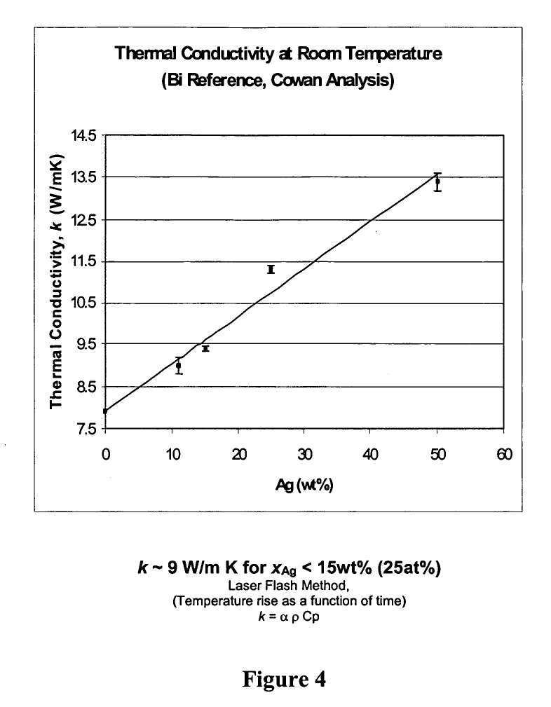

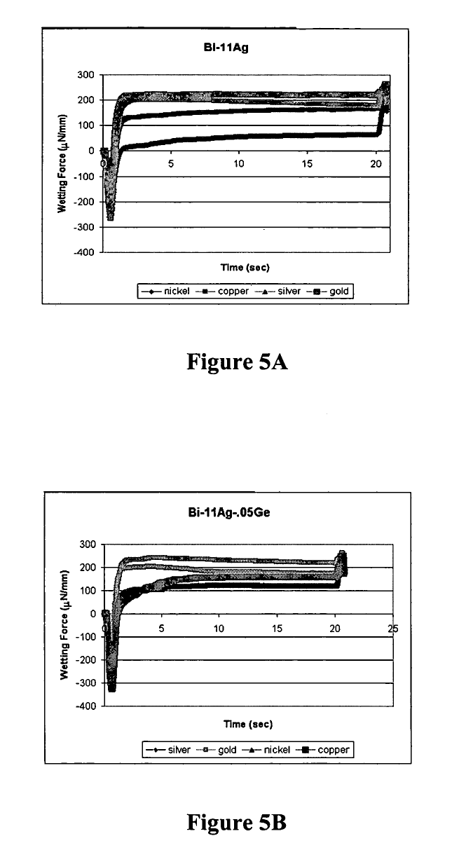

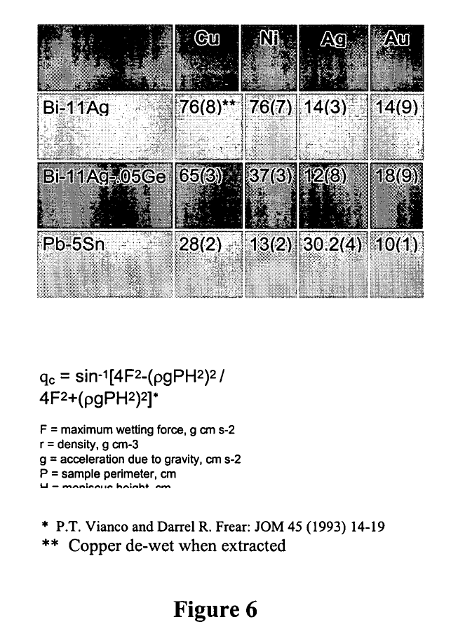

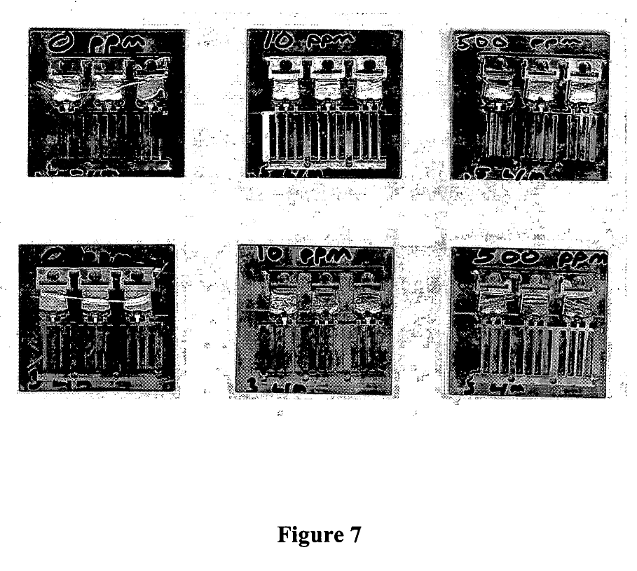

With respect to thermal conductivity of contemplated alloys, it is contemplated that compositions disclosed herein have a conductivity of no less than about 5 W/m K, more preferably of no less than about 9 W/m K, and most preferably of no less than-about 15 W/m K. Thermal conductivity analysis for some of the contemplated alloys using a laser flash method indicated thermal conductivity of at least 9 W/m K is depicted in FIG. 4. It is further contemplated that suitable compositions (e.g., Bi-11Ag with about 500 ppm Ge) include a solder having a wetting force to wet Ag, Ni, Au, or Cu of between about 125 micro-N/mm to about 235 micro-N/mm on a wetting balance after about 1 second (see e.g., exemplary graphs as shown in FIGS. 5A and 5B depicting test results of contemplated alloys on various coated substrates). The improved wettability is also reflected in the change in calculated contact angle (air, with aqueous flux) which is depicted in FIG. 6. Moreover, contemplated alloys were applied to Ni-plated leadframes under N₂/H₂ atmosphere, and the results are depicted in FIG. 7 for Bi-11Ag-xGe (x=0, 10, and 500 ppm), wherein the upper series was at a moderately low pO₂ content and the lower series was at a lower pO₂ content.

Methods of manufacturing and/or producing a doped substantially lead-free solder composition comprise a) providing at least one solder material; b) providing at least one dopant; c) combining the at least one solder material and the at least one dopant such that the dopant is present in an amount up to about 1000 ppm to form the solder composition.

Methods of manufacturing and/or producing a solder composition comprising silver and bismuth have one step in which bismuth and silver are provided in an amount of about 98 wt % to about 82 wt % and about 2 wt % to about 18 wt %, respectively, wherein the at least one of zinc, nickel, germanium, copper, calcium or a combination thereof is present in an amount of up to about 1000 ppm. In a further step, the silver, bismuth, and the at least one of zinc, nickel, germanium or a combination thereof are melted at a temperature of at least about 960° C. to form an alloy having a solidus of no lower than about 262.5° C. and a liquidus of no higher than about 400° C. Contemplated methods further include optional addition of a chemical element having an oxygen affinity that is higher than the oxygen affinity of the alloy.

### EXAMPLES

### EXAMPLE

### Silver Bismuth Solder Composition with Dopants

Due to the differences in the coefficient of thermal expansion of various materials, solder joints will frequently experience shear loading. Therefore, it is especially desirable that alloys coupling such materials have a low shear modulus and, hence, good thermomechanical fatigue resistance. For example, in die attach applications, low shear modulus and good thermomechanical fatigue help prevent cracking of a die, especially where relatively large dies are coupled to a solid support.

Based on the known elastic moduli of the pure metals, the fact that Ag and Bi exhibit partial solid miscibility, and the fact that the Ag—Bi system contains no intermetallic or intermediate phases, it has been calculated that the room temperature shear modulus of contemplated Ag—Bi alloys will be in the range of about 13-16 GPa (assuming room temperature shear modulus to be an additive property—i.e., following the rule-of-mixtures). Room temperature shear moduli in the range of about 13-16 GPa of contemplated alloys are especially favorable in comparison to 25 GPa for both Au-25% Sb and Au-20% Sn alloys (calculated by the same method and making the same assumption), and 21 GPa for Alloy J (Ag-10% Sb-65% Sn), with 22.3 GPa being a measured value for Alloy J. Further experiments confirmed previous calculations and established the following shear moduli for the following alloys: Bi-11Ag=13.28 Gpa; Bi-9Ag=13.24 Gpa; Au-20Sn=21.26 Gpa; Sn-25sb-10Ag (Alloy J)=21.72 Gpa; and Pb-5Sn=9.34 GPa. Still further experiments (data not shown) indicate that the shear strength of Bi-11Ag and Pb-5Sn are comparable.

Additional mechanical properties are depicted below in Table 1 summarizing data on liquidus, UTS, and ductility (in % elongation) for solder wire:

TABLE 1

| Alloy | Liquidus | UTS | Ductility |
|---|---|---|---|
| Pb—5Sn | 315 | 25.4 | 38.0 |
| Pb—2.5Ag—2Sn | 296 | 31.5 | 22.0 |
| Sn—8.5Sb | 246 | 52.4 | 55.0 |
| Bi—11Ag | 360 | 59.0 | 34.6 |
| Bi—11Ag—0.05Ge | 360 | 69.7 | 19.1 |
| Sn—25Ag—10Sb | 395 | 109.4 | 10.4 |

Various experiments were also performed to identify suitable concentrations of a third metal (in this case: Ge) in contemplated alloys to improve wettability of such alloys to substrates that are plated with various metals, including Ag, Ni, Au, and Cu as indicated in Table 2 (all numbers in EN/mm; phosphorus was added at 100 ppm for Cu-plated, and 1000 ppm for all other metal-plated sets):

TABLE 2

| | 5000 ppm | 2000 ppm | 1000 ppm | 500 ppm | 500 ppm | | |
|---|---|---|---|---|---|---|---|
| | Ge | Ge | Ge | Ge | Ge + 200 ppm P | Bi—9Ag | Bi—9Ag + P |
| Wrought-Cu | 200 | 200 | 200 | 200 | 200 | 100 | 150 |
| Ni-plated | 125 | 100 | 125 | 125 | 150 | 50 | 110 |
| Ag-plated | 225 | 235 | N/A | 225 | 235 | 215 | 225 |
| Au-plated | 225 | 235 | N/A | 235 | 245 | 230 | 250 |

Similarly, data were obtained for Bi-11Ag with and without addition of 500 ppm Ge, and the results are depicted in Table 3:

TABLE 3

| | 500 ppm | |
|---|---|---|
| | Ge | Bi—11Ag |
| Wrought-Cu | 185 | 165 |
| Ni-plated | 125 | 65 |
| Ag- | 225 | 215 |
| plated | | |
| Au- | 235 | 230 |
| plated | | |

Thus, addition of Ge to Bi-11Ag increases the maximum wetting force (μN/mm) as indicated in Table 4:

TABLE 4

| | Bi—11Ag | Plus P | Plus Ge |
|---|---|---|---|
| Wrought-Cu | ˜90 | ˜125 | ˜200 |
| Ni-plated | ˜50 | ˜110 | ˜125 |

While addition of germanium to increase the wetting force is contemplated, it should also be appreciated that numerous alternative elements (especially nickel, zinc and or combinations thereof with or without germanium) are also considered suitable for use herein, and particularly contemplated elements include those that can form intermetallic complexes with the metal to which the alloy is bonded.

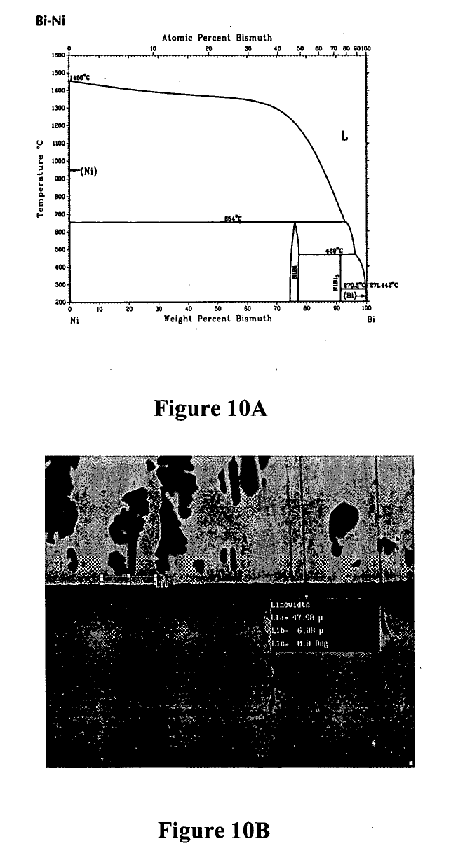

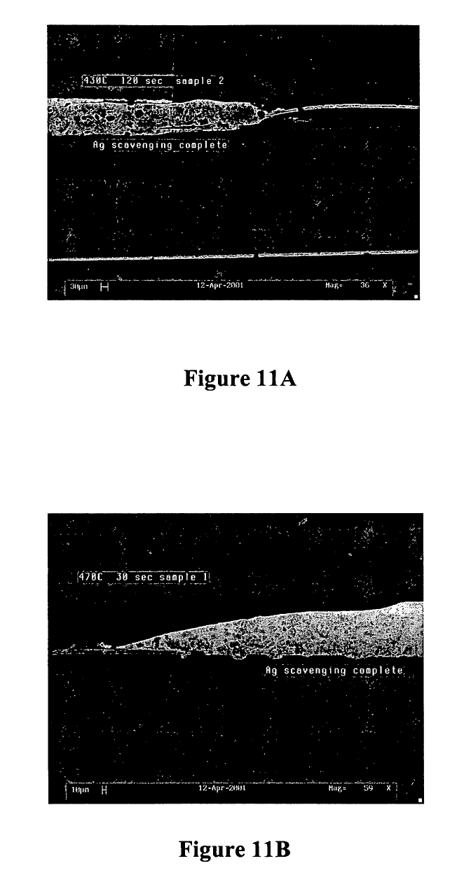

Test assemblies constructed of a silicon die bonded to a leadframe with Ag-89% Bi alloy have shown no visible signs of failure after 1500 thermal aging cycles, which is in further support of the calculated and observed low shear modulus of contemplated Ag—Bi alloys. In a further set of experiments, contemplated alloys were bonded to a Ni-plated substrate. As could be anticipated from the Ni—Bi phase diagram depicted in FIG. 10A, intermetallic complexes may be formed at the Ni-solder alloy interface as shown in FIG. 10B. Similarly, contemplated alloys were bonded on a Ag-plated substrate, and silver scavenging could be observed under conditions as indicated in FIGS. 11A and 11B.

Bond strength measurements were performed with various samples, and the results and average of the samples are indicated in Table 5 below (MIL-STD-883E Method 2019.5 calls for a minimum force of 2.5 kg or a multiple thereof):

TABLE 5

| Unit Number | Die Size (cm²) | Shear Strength (kg) | Remarks |
|---|---|---|---|
| 1 | 0.2025 | 25.0 | Cohesive failure |
| 2 | 0.2025 | 53.7 | Die chipped off |
| 3 | 0.2025 | 29.0 | Cohesive failure |
| 4 | 0.2025 | 24.6 | Die still intact |
| 5 | 0.2025 | 32.6 | Die still intact |
| 6 | 0.2025 | 22.0 | |
| 7 | 0.2025 | 32.6 | |
| 8 | 0.2025 | 69.5 | |
| 9 | 0.2025 | 28.2 | |
| 10 | 0.2025 | 20.7 | |
| 11 | 0.2025 | 14.1 | |
| 12 | 0.2025 | 18.9 | |
| Average | 0.2025 | 30.9 | |

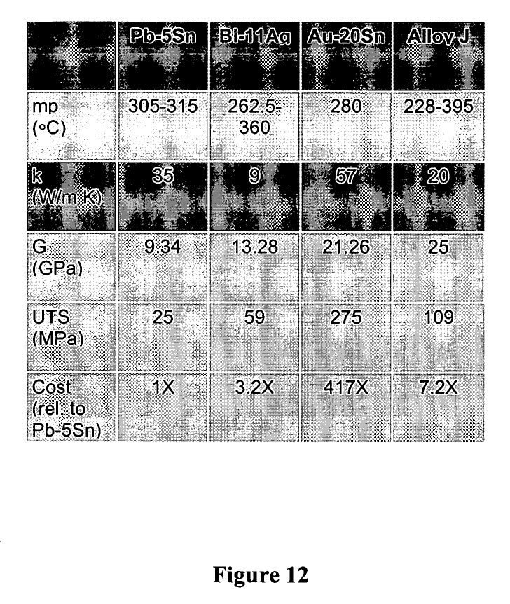

A summary of some of the physical properties and cost of contemplated alloys (and comparative alloys) is depicted in FIG. 12, which clearly demonstrates the overall advantage of contemplated alloys.

### EXAMPLE

### Solders with Copper and Phosphorus Dopants

The metallization on a substrate, package or board to which electrical interconnects, such as BGA spheres, are typically bonded is usually copper. Copper reacts rapidly with the major constituent of most solders (tin) to form Cu—Sn intermetallic compounds, which grows rapidly and can exhibit spalling or breakage from the interface. This breakage reduces the strength and integrity of the solder joint.

To reduce consumption of the bond pad, barrier layers that prevent direct contact of Sn and Cu are utilized. These additional layers are often referred to as bond pad metallurgy or under bump metallurgy (UBM). Bond pad metallurgy for BGA spheres typically has involved the use of nickel-plating to provide a barrier layer for the copper and a thin coating of gold to maintain solderability. While nickel will interact with Sn to form intermetallic compounds, the intermetallic growth rates are substantially slower than those of Cu-Sn intermetallics. Historically, electrolytic nickel plating has been used. The nickel deposit in this type of plating is fairly pure, with few co-deposits of undesirable elements, such as phosphorus.

To reduce cost to manufacture, a newer type of plating—electroless nickel (EN) followed by immersion gold (IG) is being implemented. The electroless nickel deposition baths typically will involve the use of a hypophosphite (H2PO2-) solution that leads to phosphorus co-deposits in EN coatings to a level of 7-15 atom %. This additional phosphorous can cause problems during the IG plating and in reflow or subsequent thermal excursions. Lower phosphorus content coatings perform poorly in corrosion resistance during IG plating, requiring users to aim for higher phosphorus deposits.

During solder reflow, the thin IG coating is dissolved almost instantly. The tin in the solder then reacts with the nickel in the EN coating to form Ni—Sn intermetallics. Phosphorus is not involved in this intermetallic formation, so as the intermetallic compound grows at elevated temperatures, more and more phosphorus is rejected at the intermetallic interface. This phosphorus can accumulate in a thin phosphorus-rich Ni—P layer, which weakens the solder joint, or as crystalline Ni—P, which will also weaken the solder joint. Solder joint failures occur through this phosphorus rich layer. These types of failures are known in the industry as “Black Pad” failures, as the phosphorus rich layer that is exposed by the failure can have a blackish appearance. Since intermetallics can grow rapidly even in the solid state when the joint is exposed to elevated temperatures, these failures can occur in thermally aged joints that appeared to be good immediately after solder reflow.

One example of doped solder compositions comprise at least one solder material, at least one phosphorus-based dopant and at least one copper-based dopant. Methods of forming doped solder composition described herein comprise: a) providing at least one solder material; b) providing at least one phosphorus-based dopant; c) providing at least one copper-based dopant, and d) blending the at least one solder material, the at least one phosphorus-based dopant and the at least one copper-based dopant to form a doped solder material. In contemplated embodiments, the dopants of copper and phosphorus that are added to the solder alloy or material reduce the consumption of the Electroless Nickel (EN) plated barrier layer. The dopants are added to the solder alloy that could be used to produce powders, paste, ingots, wire, preforms or BGA spheres through a process such as that described in commonly-owned U.S. Issued Pat. No. 6,579,479, which is incorporated herein in its entirety by reference.

Layered materials are also contemplated herein that comprise: a) a surface or substrate; b) an electrical interconnect; c) a solder composition comprising a phosphorus-based dopant and a copper-based dopant, such as those described herein, and d) a semiconductor die or package. Contemplated surfaces may comprise a printed circuit board or a suitable electronic component. Electronic and semiconductor components that comprise solder materials and/or layered materials described herein are also contemplated.

Contemplated embodiments described herein differ from the cited references in that the concentrations of alloying additions made and in the use of phosphorus as an additive to the solder are different and surprisingly effective. High levels of copper in the solder are shown in multiple papers, such as the Jeon papers cited previously herein, to lower the consumption of the intermetallic layer. The levels utilized herein are lower by a factor of 2.5->10. The work by Ho shows that a different intermetailic forms at the nickel/solder interface for copper compositions below 0.2% (2000 ppm). The combination of copper and phosphorus was not noted anywhere in the levels of the subject matter presented herein. The mechanisms for reducing nickel consumption are different for each element.

Also, the Niedrich patents described previously herein use copper to inhibit nickel barrier layer interaction through forming copper intermetallics or (Cu, Ni)Sn intermetallics. The Niedrich patents are very similar in their use of copper as U.S. Pat. No. 2,671,844, which adds copper to solder in amounts greater than 0.5 wt % to minimize dissolution of copper soldering iron tips during fine soldering operations. Both of these copper additions need to be significantly higher than the amounts contemplated herein. The same is true for the Ozaki patent, wherein the addition of copper is significantly higher than the amounts contemplated herein.

Contemplated dopants comprise at least one phosphorus-based compound/dopant and at least one copper-based compound/dopant. Dopant levels contemplated herein are less than about 100 ppm for phosphorus and less than about 800 ppm for copper. In some embodiments, the dopant levels are contemplated to be about 10-100 ppm for phosphorus and about 25-800 ppm copper. In some embodiments, the dopant levels are contemplated to be about 10-70 ppm for phosphorus and about 25-500 ppm copper. In other embodiments, the dopant levels are contemplated to be about 20-60 ppm for phosphorus and about 40-600 ppm copper. In yet other embodiments, the dopant levels are contemplated to be about 30-60 ppm for phosphorus and about 300-500 ppm copper.

These dopant materials could be added to the solder main constituents directly during casting. When small amounts of dopant are used, it may be desirable to make a master alloy and dilute that with undoped solder for better control over dopant concentration.

The at least one solder material, the at least one phosphorus-based compound/dopant and/or the at least one copper-based compound/dopant may be provided by any suitable method, including a) buying the at least one solder: material, the at least one phosphorus-based compound/dopant and/or the at least one copper-based compound/dopant a supplier; b) preparing or producing at least some of the at least one solder material, the at least one phosphorus-based compound/dopant and/or the at least one copper-based compound/dopant a supplier in house using chemicals provided by another source and/or c) preparing or producing the at least one solder material, the at least one phosphorus-based compound/dopant and/or the at least one copper-based compound/dopant a supplier in house using chemicals also produced or provided in house or at the location.

Applications

In the test assemblies and various other die attach applications the solder is generally made as a thin sheet that is placed between the die and the substrate to which it is to be soldered. Subsequent heating will melt the solder and form the joint. Alternatively the substrate can be heated followed by placing the solder on the heated substrate in thin sheet, wire, melted solder, or other form to create a droplet of solder where the semiconductor die is placed to form the joint.

For area array packaging contemplated solders can be placed as a sphere, small preform, paste made from solder powder, or other forms to create the plurality of solder joints generally used for this application. Alternatively, contemplated solders may be used in processes comprising plating from a plating bath, evaporation from solid or liquid form, printing from a nozzle like an ink jet printer, or sputtering to create an array of solder bumps used to create the joints.

In a contemplated method, spheres are placed on pads on a package using either a flux or a solder paste (solder powder in a liquid vehicle) to hold the spheres in place until they are heated to bond to the package. The temperature may either be such that the solder spheres melt or the temperature may be below the melting point of the solder when a solder paste of a lower melting composition is used. The package with the attached solder balls is then aligned with an area array on the substrate using either a flux or solder paste and heated to form the joint.

A preferred method for attaching a semiconductor die to a package or printed wiring board includes creating solder bumps by printing a, solder paste through a mask, evaporating the solder through a mask, or plating the solder on to an array of conductive pads. The bumps or columns created by such techniques can have either a homogeneous composition so that the entire bump or column melts when heated to form the joint or can be inhomogeneous in the direction perpendicular to the semiconductor die surface so that only a portion of the bump or column melts.

It is still further contemplated that a particular shape of contemplated compositions is not critical to the inventive subject matter. However, it is preferred that contemplated compositions are formed into a wire shape, ribbon shape, or a spherical shape (solder bump).

Solder materials, spheres and other related materials described herein may also be used to produce solder pastes, polymer solders and other solder-based formulations and materials, such as those found in the following Honeywell International Inc.'s issued patents and pending patent applications, which are commonly-owned and incorporated herein in their entirety: U.S. patent application Ser. Nos. 09/851103, 60/357754, 60/372525, 60/396294, and 09/543628; and PCT Pending Application Ser. No. PCT/US02/14613, and all related continuations, divisionals, continuation-in-parts and foreign applications. Solder materials, coating compositions and other related materials described herein may also be used as components or to construct electronic-based products, electronic components and semiconductor components. In contemplated embodiments, the alloys disclosed herein may be used to produce BGA spheres, may be utilized in an electronic assembly comprising BGA spheres, such as a bumped or balled die, package or substrate, and may be used as an anode, wire or paste or may also be used in bath form.

Also in contemplated embodiments, the spheres are attached to the package/substrate or die and reflowed in a similar manner as undoped spheres. The dopant slows the consumption rate for the EN coating and results in higher integrity (higher strength) joints.

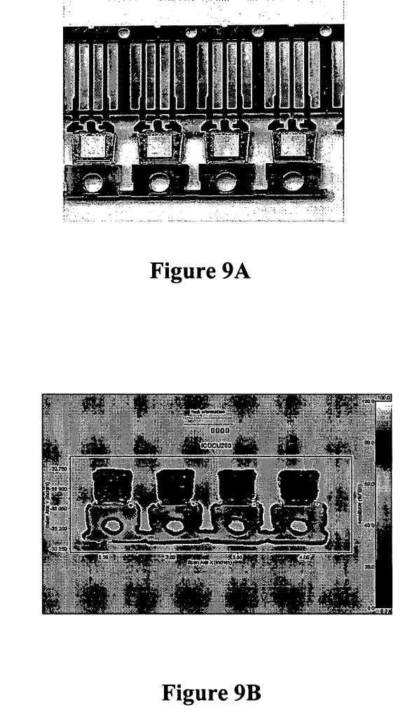

Among various other uses, contemplated compounds (e.g., in wire form) may be used to bond a first material to a second material. For example, contemplated compositions (and materials comprising contemplated compositions) may be utilized in an electronic device to bond a semiconductor die (e.g., silicon, germanium, or gallium arsenide die) to a leadframe as depicted in FIG. 8. Here, the electronic device 100 comprises a leadframe 110 that is metallized with a silver layer 112. A second silver layer 122 is deposited on the semiconductor die 120 (e.g., by backside silver metallization). The die and the leadframe are coupled to each other via their respective silver layers by contemplated composition 130 (here, e.g., a solder comprising an alloy that includes Ag in an amount of about 2 wt % to about 18 wt % and Bi in an amount of about 98 wt % to about 82 wt %, wherein the alloy has a solidus of no lower than about 262.5° C. and a liquidus of no higher than about 400° C.). In an optimum die attach process, contemplated compositions are heated to about 40° C. above the liquidus of the particular alloy for 15 seconds and preferably no higher than about 430° C. for no more than 30 seconds. The soldering can be carried out under a reducing atmosphere (e.g., hydrogen or forming gas). A die attachment experiment was performed using a solder wire comprising contemplated alloys with a Ni-coated leadframe and a semiconductor die as shown in FIGS. 9A (photograph) and 9B (SAM [Scanning acoustic microscopy] analysis).

In further alternative aspects, it is contemplated that the compounds disclosed herein may be utilized in numerous soldering processes other than die attach applications. In fact, contemplated compositions may be particularly useful in all, or almost all, step solder applications in which a subsequent soldering step is performed at a temperature below the melting temperature of contemplated compositions. Furthermore, contemplated compositions may also be utilized as a solder in applications where high-lead solders need to be replaced with lead-free solders, and solidus temperatures of greater than about 240° C. are desirable. Particularly preferred alternative uses include use of contemplated solders in joining components of a heat exchanger as a non-melting standoff sphere or electrical/thermal interconnection.

Electronic-based products can be “finished” in the sense that they are ready to be used in industry or by other consumers. Examples of finished consumer products are a television, a computer, a cell phone, a pager, a palm-type organizer, a portable radio, a car stereo, and a remote control. Also contemplated are “intermediate” products such as circuit boards, chip packaging, and keyboards that are potentially utilized in finished products.

Electronic products may also comprise a prototype component, at any stage of development from conceptual model to final scale-up/mock-up. A prototype may or may not contain all of the actual components intended in a finished product, and a prototype may have some components that are constructed out of composite material in order to negate their initial effects on other components while being initially tested.

As used herein, the term “electronic component” means any device or part that can be used in a circuit to obtain some desired electrical action. Electronic components contemplated herein may be classified in many different ways, including classification into active components and passive components. Active components are electronic components capable of some dynamic function, such as amplification, oscillation, or signal control, which usually requires a power source for its operation. Examples are bipolar transistors, field-effect transistors, and integrated circuits. Passive components are electronic components that are static in operation, i.e., are ordinarily incapable of amplification or oscillation, and usually require no power for their characteristic operation. Examples are conventional resistors, capacitors, inductors, diodes, rectifiers and fuses.

Electronic components contemplated herein may also be classified as conductors, semiconductors, or insulators. Here, conductors are components that allow charge carriers (such as electrons) to move with ease among atoms as in an electric current. Examples of conductor components are circuit traces and vias comprising metals. Insulators are components where the function is substantially related to the ability of a material to be extremely resistant to conduction of current, such as a material employed to electrically separate other components, while semiconductors are components having a function that is substantially related to the ability of a material to conduct current with a natural resistivity between conductors and insulators. Examples of semiconductor components are transistors, diodes, some lasers, rectifiers, thyristors and photosensors.

Electronic components contemplated herein may also be classified as power sources or power consumers. Power source components are typically used to power other components, and include batteries, capacitors, coils, and fuel cells. As used herein, the term “battery” means a device that produces usable amounts of electrical power through chemical reactions. Similarly, rechargeable or secondary batteries are devices that store usable amounts of electrical energy through chemical reactions. Power consuming components include resistors, transistors, ICs, sensors, and the like.

Still further, electronic components contemplated herein may also be classified as discreet or integrated. Discreet components are devices that offer one particular electrical property concentrated at one place in a circuit. Examples are resistors, capacitors, diodes, and transistors. Integrated components are combinations of components that that can provide multiple electrical properties at one place in a circuit. Examples are ICs, i.e., integrated circuits in which multiple components and connecting traces are combined to perform multiple or complex functions such as logic.

Solder compositions contemplated herein may also comprise at least one support material and/or at least one stability modification material, such as those described in PCT Application PCT/US03/04374, which is commonly-owned and incorporated herein by reference. The at least one support material is designed to provide a support or matrix for the at least one metal-based material in the solder paste formulation. The at least one support material may comprise at least one rosin material, at least one rheological additive or material, at least one polymeric additive or material and/or at least one solvent or solvent mixture. In some contemplated embodiments, the at least one rosin material may comprise at least one refined gum rosin.

Stability modification materials and compounds, such as humectants, plasticizers and glycerol-based compounds may also positively add to the stability of the solder composition over time during storage and processing and are contemplated as desirable and often times necessary additives to the solder paste formulations of the subject matter presented herein. Also, the addition of dodecanol (lauryl alcohol) and compounds that are related to and/or chemically similar to lauryl alcohol contribute to the positive stability and viscosity results found in contemplated solder paste formulation and are also contemplated as desirable and sometimes necessary additives to contemplated solder paste formulations. Further, the addition or replacement of an amine-based compound, such as diethanolamine, triethanolamine or mixtures thereof may improve the wetting properties of the paste formulation to the point where it is inherently more printable in combination with the stencil apparatus, and therefore, more stable over time and during processing. Dibasic acid compounds, such as a long-chain dibasic acid, can be also used as a stability modification material.

Thus, specific embodiments and applications of doped solder materials and solder dopants utilized as electronic interconnects have been disclosed. It should be apparent, however, to those skilled in the art that many more modifications besides those already described are possible without departing from the inventive concepts herein. Moreover, in interpreting the specification, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A lead free solder composition, comprising:
at least one solder material; and
at least one dopant material, wherein the dopant is present in the material in an amount of less than about 1000 ppm, and wherein the solder composition is substantially lead free.

2. The lead free solder composition of claim 1, comprising:
a solder material comprising an alloy that comprises Ag in an amount of about 2 wt % to about 18 wt %, Bi in an amount of about 98 wt % to about 82 wt %, and
at least one of zinc, nickel, germanium or a combination thereof in an amount of up to about 1000 ppm, wherein the alloy has a solidus of no lower than about 262.5° C. and a liquidus of no higher than about 500° C.

3. The composition of claim 2, wherein the at least one of zinc, nickel, germanium, copper, calcium or a combination thereof is present in an amount of about 500 ppm.

4. The composition of claim 1, further comprising a chemical element having an oxygen affinity that is higher than the oxygen affinity of at least one of the primary constituents of the alloy.

5. The composition of claim 5, wherein the chemical element is phosphorus.

6. The composition of claim 5, wherein the chemical element is present in a concentration of up to about 1000 ppm.

7. The composition of claim 1, wherein the alloy is formed into at least one of a wire, a ribbon, a preform, an anode, a sphere, a paste, and an evaporation slug.

8. The composition of claim 1, further comprising a chemical element that forms an intermetallic complex or compound with nickel, copper, gold, silver or a combination thereof.

9. The composition of claim 8, wherein the chemical element is phosphorus or germanium.

10. The composition of claim 9, wherein the chemical element is present in a concentration of up to about 1000 ppm.

11. An electronic device comprising a semiconductor die coupled to a surface via a material comprising the composition according to claim 1.

12. A doped solder composition comprising:
at least one solder material,
at least one phosphorus-based dopant; and
at least one copper-based dopant.

13. The doped solder material of claim 12, wherein the at least one solder material comprises indium, silver, copper, aluminum, tin, bismuth, gallium and alloys thereof, silver coated copper, silver coated aluminum or a combination thereof.

14. The doped solder material of claim 13, wherein the at least one solder material comprises silver-based compounds and alloys, indium tin (InSn) compounds and alloys, indium silver (InAg) compounds and alloys, indium-based compounds, tin silver copper compounds and alloys (SnAgCu), tin bismuth compounds and alloys (SnBi), aluminum-based compounds and alloys and combinations thereof.

15. The doped solder material of claim 12, wherein the at least one phosphorus-based dopant is present in an amount less than about 100 ppm phosphorus.

16. The doped solder material of claim 15, wherein the at least one phosphorus-based dopant is present in an amount less than about 70 ppm phosphorus.

17. The doped solder material of claim 16, wherein the at least one phosphorus-based dopant is present in an amount less than about 60 ppm phosphorus.

18. The doped solder material of claim 12, wherein the at least one copper-based dopant is present in an amount less than about 800 ppm copper.

19. The doped solder material of claim 18, wherein the at least one copper-based dopant is present in an amount less than about 600 ppm copper.

20. The doped solder material of claim 19, wherein the at least one copper-based dopant is present in an amount less than about 500 ppm copper.

21. A layered material, comprising:
a surface or substrate;
an electrical interconnect;
a solder composition comprising at least one solder material; at least one dopant material, wherein the dopant is present in the material in an amount of less than about 1000 ppm, and wherein the solder composition is substantially lead-free.

22. A layered material, comprising:
a surface or substrate;
an electrical interconnect;
a solder composition comprising at least one phosphorus-based dopant and at least one copper-based dopant; and
a semiconductor die or package.

23. An electronic component comprising the doped solder composition of either claim 1 or claim 12.

24. A semiconductor component comprising the doped solder composition of either claim 1 or claim 12.
